(19) United States
(12) Patent Application Publication
(10) Pub. No.: US 2021/0195801 A1
(43) Pub. Date: Jun. 24, 2021

(54) DISTRIBUTION POINT UNIT (DPU) WITH IMPROVED THERMAL MANAGEMENT AND ELECTRICAL ISOLATION

(71) Applicant: NETCOMM WIRELESS PTY LTD, Lane Cove, New South Wales (AU)

(72) Inventors: Karl VERRAN, Lane Cove (AU); Gilby CHACKO, Lane Cove (AU); Paul MATHIEU, Lane Cove (AU)

(73) Assignee: NETCOMM WIRELESS PTY LTD, Lane Cove, New South Wales (AU)

(21) Appl. No.: 16/768,297

(22) PCT Filed: Oct. 12, 2018
(86) PCT No.: PCT/AU2018/051112

§ 371 Date: May 29, 2020

(30) Foreign Application Priority Data
Dec. 5, 2017 (AU) 2017904883

(51) Int. Cl. H05K 7/20; H05K 5/04

(52) U.S. Cl. CPC H05K 7/20454; H05K 5/04; H04B 10/25; H05K 7/20409; H05K 7/2049

(57) ABSTRACT

A Distribution Point Unit (DPU) (10) having improved thermal management and electrical isolation, wherein a first mechanical fastener (200) engages with a first heat sink (50) and is configured to draw the first heat sink (50) towards the interior surface of a housing (31) in response to tightening of the first mechanical fastener (200) such that the first heat sink (50) becomes substantially flush with the interior surface of the housing (31); and wherein a first thermal pad (90) is electrically insulative to electrically isolate the first heat sink (50).

### FIELD OF THE INVENTION

The present invention relates to a Distribution Point Unit (DPU) with improved thermal management and electrical isolation. The DPU is used in data communication networks that employ both fibre optic and copper lines.

### BACKGROUND TO THE INVENTION

FTTdp (Fiber to the Distribution Point) brings the fibre optic connection point of a fibre-optic telecommunications network closer to the premises (home) of an end user (customer) in comparison to Fiber to the Node (FTTN) broadband architectures. FTTdp requires access to Customer Premises Equipment (CPE) located at the premises of a customer and which includes, as a minimum, a modem and POTS (Plain Old Telephony System) wiring. In this broadband network architecture the last few meters (e.g. up to 200 metres) of the broadband connection supplied through a passive optical network (PON) are provided by the existing twisted pair cabling or copper wire (copper lead-ins) to the premises that is currently used for legacy technologies such as POTS and xDSL.

In a gigabit passive optical network (GPON), networking protocols can provide 2.4 Gbps download speed for up to 20 kilometres and the NG-PON2 networking protocol can provide 40 Gbps download speed for up to 60 kilometres. To match the increased speed capabilities that come with bringing the fiber nodes closer to the home, the access technology through the copper wire is improving to provide higher data transfer speeds. Such access technology on the copper wire can include G.fast (1 Gbps download speed for up to 100 metres) and its successor XG.FAST (3.5 Gbps download speed for up to 100 metres). The signal frequency of G.fast starts at 106 MHz (it can be doubled to 212 MHz) and XG.fast uses between 350 MHz and 500 MHz. This copper wire access technology provides more bandwidth for transferring data over copper at higher speeds. To address the problem of signal attenuation at higher frequencies, G.fast and XG.FAST both use vectoring to generate an anti-phase signal to cancel the majority of interference.

A distribution point unit (DPU) is typically a small piece of telecommunications equipment that is used in broadband network architecture such as FTTdp. In use, the DPU is placed in an existing underground communications pit or secured outdoors to a wall or power pole, depending on suitability and other factors. In one example, the DPU includes one fibre-optic cable port or tail for its upstream connection to the optical network, an optical-electrical signal converter that converts incoming optical signal and electrical signals into electrical and optical signals, depending on traffic direction to/from the premises, and directs network traffic to four or more downstream copper wire or coaxial cable ports or fly wires of the DPU. The downstream connections connect to a device for connecting the premises to the telecommunications network, such as a Network Connection Device (NCD), for example, the modem at the customer (user) premises. A Reverse Power Unit (RPU) located at the premises provides a power feed to the DPU via the copper wire.

The placement of the DPU in the external environment requires it to be environmentally hardened to withstand harsh and varied weather and environmental conditions for many years. The DPU should be operable in very challenging circumstances such as immersion in water or mud, and long exposure to direct sunlight in summer. The DPU should operate in extreme temperatures since temperatures can range from −23° C. to 51° C. in certain countries.

Other criteria for DPUs include that they are required to be tamper-resistant, capable of sending a notification if they have been tampered with, be inexpensive to manufacture and install, and the connections at the DPU should be accessible outside the DPU housing to enable a technician of a network provider to connect them with copper lead-ins and the fibre-optic cable leading to the DPU without opening the DPU housing.

It is an important function of a DPU to manage the temperature of its electronics. The DPU needs to dissipate towards the environment heat generated from electronic components and optical components housed within the DPU during operation to avoid these components over-heating beyond a maximum operating temperature range. Over-heating may cause the DPU to be unstable, unreliable and malfunction and therefore require a technician to make an on-site visit to repair or replace the DPU. Thus, metallic housing components are often used to ensure adequate heat transfer away from electronic components. However, it is equally essential to ensure electrical isolation of relevant components housed within the DPU. Finding a suitable lay out that addresses these two requirements is not a straight forward exercise.

### SUMMARY OF THE INVENTION

The inventive concept arises from a recognition that effective thermal management and electrical isolation of electrical components from the metallic housing components of the DPU enables the DPU to have long term reliability. A particular challenge arises in the context of hermetically sealed DPUs that prevent the ingress of dirt and moisture when the DPU is installed in a harsh environment. The inventive concept recognises that passive thermal management, relying solely on the thermo-dynamics of conduction, convection and radiation to complete the heat transfer process, is important in such cases.

In a first aspect, the present invention provides a Distribution Point Unit (DPU), comprising an at least partially metallic housing having an exterior surface and interior surface. The DPU further comprises an electronic board including electronic components housed within the housing. The DPU further comprises at least one heat sink housed in displaceable manner within the housing and configured to conduct heat generated by at least some of the electronic components at the electronic board into the housing. The DPU further has at least one resilient thermal pad placed between one side of the electronic board and the heat sink in at least partial, physical contact making engagement, the thermal pad being heat conductive and electrically insulating to electrically isolate the first heat sink from the electronic board components. Finally, the DPU also includes at least one mechanical fastener engaging with the heat sink and operable from an exterior of the housing, the arrangement being such that in response to tightening of the mechanical fastener (i) the heat sink is pressed against the interior surface of the housing to maintain contact (and preferably a force fit) between the heat sink and the interior surface and (ii) the engagement between the thermal pad, the heat sink and components of the electronic board is maintained.

The present invention, in another aspect, provides a Distribution Point Unit (DPU) having improved thermal management and electrical isolation. The DPU comprises an at least partially metallic housing having an exterior surface and interior surface. The DPU also comprises an electronic board including electronic components housed within the housing. The DPU also comprises a first resilient thermal pad placed on a first side of the electronic board. The DPU also comprises a first heat sink configured to rest against the first thermal pad. The DPU also comprises a first mechanical fastener that is operable from an exterior of the housing, and which engages with the first heat sink. The configuration is such as to draw the first heat sink against the interior surface of the housing in response to tightening of the first mechanical fastener, whereby intimate physical (or positive) contact between the first heat sink and the interior surface of the housing is achieved. The first thermal pad is heat conductive and electrically insulative to electrically isolate the first heat sink. The first thermal pad is devised such that during tightening of the first mechanical fastener, its resilient nature and shape allows it to maintain surface-contact with the electronic board as well as the first heat sink, thereby providing a heat dissipation path between electronic components of the electronic board and the interior surface of the housing.

Preferably, the heat dissipation path between the electronic components, first thermal pad, first heat sink and the at least partially metallic housing is substantially without an air gap.

The DPU may further comprise a second resilient thermal pad placed on a second side opposite the first side of the electronic board. The DPU may further comprise a second heat sink configured to rest against the second thermal pad. The DPU may further comprise a second mechanical fastener that is operable from the exterior of the housing, and which engages with the second heat sink. The configuration is such as to draw the second heat sink against the interior surface of the housing in response to tightening of the second mechanical fastener, whereby intimate physical (or positive) contact between the second heat sink and the interior surface of the housing is achieved. The second thermal pad is electrically insulative to electrically isolate the second heat sink. The second thermal pad is devised such that during tightening of the second mechanical fastener, its resilient nature and shape allows it to maintain surface-contact with the electronic board as well as the second heat sink, thereby providing a heat dissipation path between electronic components of the electronic board and the interior surface of the housing. Preferably, the heat dissipation path is substantially without an air gap.

The above described arrangement allows mounting of the electronic board in electrically isolated manner within the at least partially metallic housing, and then drawing the first (and second) heat sink(s) into an essentially forced (and positive), abutting contact with the inside surface of the housing, whilst the first (and second) thermal pad(s) maintain physical contact with all or at least the most relevant, heat-generating components of the DPU attached to the electronic board. It will be understood that the physical contact need not extend to all heat-generating components, as long as the majority thereof remain in heat-conducting contact with the thermal pad(s).

The DPU may further comprise a first manifold and preferably a second manifold configured to support the electronic board and prevent physical contact between the electronic board and the at least partially metallic housing, and for positioning the heat sinks relative to the electronic board. The manifold(s) are advantageously comprised of a selected electrically insulating material, and may also comprise materials conducive to heat transfer from the electronic board to the partially metallic housing. Physical isolation helps with surge protection and enables the DPU to be installed without an external grounding point. Installing an earth point or grounding point may frequently cost more than the entire installation cost of the DPU. Therefore there is a cost advantage in providing a DPU that does not require an external earth.

The mechanical fastener may comprise an integral deformable radial sealing member arranged to seal an interface between the fastener and a port or opening through which the fastener extends into the inside of the at least partially metallic housing.

The mechanical fastener may be a sealing screw with an integral or separate o-ring.

The thermal pad(s) can advantageously be made from a silicone elastomer loaded with thermal conductive filler to provide both thermal conductivity as well as the required resilient compressibility degree to ensure physical contact is maintained between most if not all the heat-generating components housed on the electronic board and the heat sinks as these are displaced into forced abutment with the inner surface of the at least partially metallic housing.

The thermal pad(s) may be made from SR-1000C thermal conductive silicone rubber.

Noting that electronic boards (such as PCBAs) typically carry most components on one side and the opposite side is used to provide the electrically conductive tracks between components, and assuming centric positioning of the board proper within the at least partially metallic housing with respect to its mayor external walls, it is advantageous to provide the second thermal pad with a thickness that is greater than that of the first pad. This allows the second thermal pad to expand (i.e. undergo the same degree of decompression) by the same degree as the first thermal pad in the process of moving the first and second heat sinks into pressed-on engagement against the inner surfaces of the at least partially metallic housing.

Advantageously, the second heat sink may be larger geometrically or by mass than the first heat sink. This measure caters for differential heat generation at the component carrying (first) side of the electronic board and the (second) side of the board where the electrically conductive tracks prevail.

Preferably, the first heat sink can comprise a threaded hole to receive the first mechanical screw fastener, and the hole is preferably located about the centre of the first heat sink to achieve even tightening of the first heat sink against the inner surface of the housing upon tightening via the first mechanical fastener. Advantageously, a similar arrangement will be present at the second heat sink.

Advantageously, the first and the second heat sinks will exhibit a substantially planar engagement surface which can be brought into planar abutment against the inner surface of the at least partially metallic housing, thereby to provide an increased heat transfer area.

The heat sink bodies will preferably be made from a same metallic material as those parts of the housing that are metallic, thereby minimising contact corrosion and achieving even heat transfer across the interface of the abutting components.

In order to improve heat transfer to an exterior of the at least partially metallic housing, the outer surface can be provided with heat dissipation ribs or similar structures.

Other advantages and preferred features according to the invention will become apparent to those of ordinary skill upon reading the following description of preferred, non-limiting embodiments of the invention described with reference to the accompanying figures in which like reference numbers denote like elements.

### BRIEF DESCRIPTION OF THE DRAWINGS

FIG. 1 is a perspective view of a DPU incorporating various thermal and electric insulation management aspects in accordance with the present invention;

FIG. 2 is a partially exploded perspective view showing the main components of the DPU of FIG. 1, including an inner DPU-subassembly comprising a PCBA with an opto-electronic converter, an electrically isolating PCBA support structure and heat sink elements, an outer metallic casing and a housing end-cap comprising the optical and electrical connections for coupling the DPU between an optical cable network and POTS wire infrastructure (not shown);

FIG. 3 is an exploded perspective view of the inner DPU-subassembly illustrated in FIG. 2, illustrating its main components; and

FIG. 4 is a side elevation of the DPU of FIG. 1 in assembled state, partially in section.

### DETAILED DESCRIPTION OF THE INVENTION

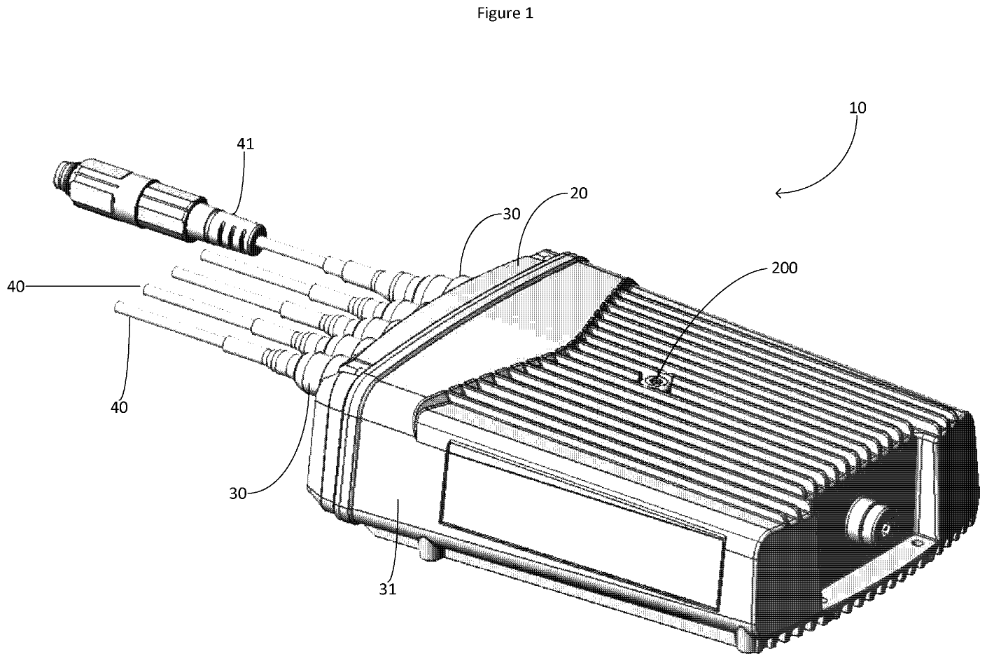

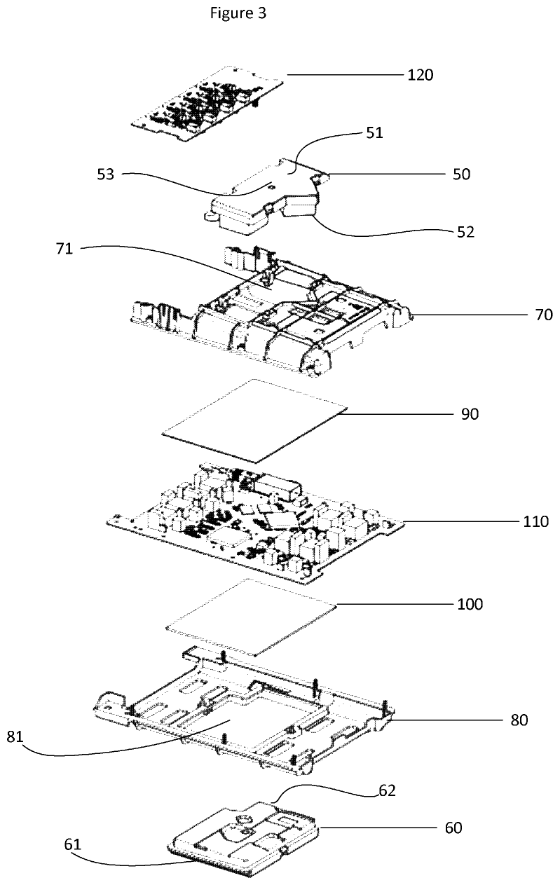

A distribution point unit (DPU) is illustrated in FIG. 1 and shown generally at reference numeral 10. The DPU 10 comprises a casing 31 including an end cap 20. The casing 31 is also referred to as an enclosure or housing. The end cap 20 is where optical cable 40 and electrical cables 41 are securely attached and sealed. The end cap 20 comprises at least one port 30 for entry of at least one cable 40 carrying optical signals and four additional ports 30 for cables 41 carrying electrical signals. The DPU 10 also comprises an electronic board (e.g. a PCBA 110, see FIG. 3) comprising electronic components for processing the optical and electrical signals carried via cables 40, 41 and transcribing these information carrier formats, as is known in the art, as well as power circuitry required for running electronic components.

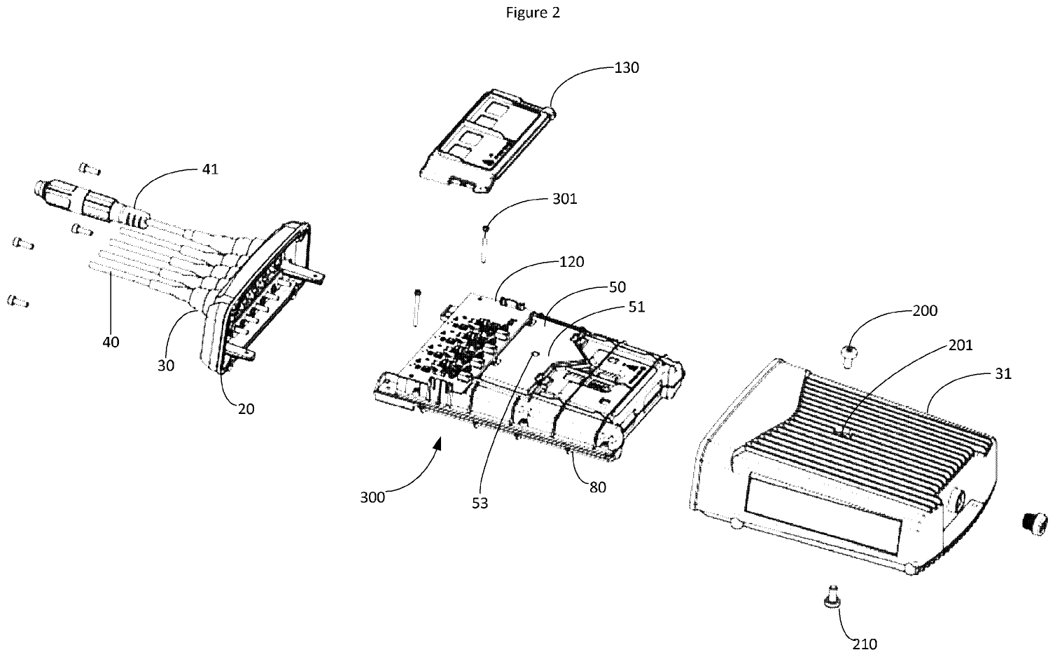

As best seen in FIGS. 2 and 3, the PCBA 110 is housed a support structure 70, 80 which, as a sub-assembly 300, is inserted and secured within the casing 31 to protect the entire sub-assembly 300 from damage and being contaminated by water and dust. The end cap 20 is devised to hermetically seal-off the open end of casing 31 and be secured to casing 31 in replaceable manner.

The DPU housing 31 is made from aluminium. Electrical isolation between the electronics carried on the PCBA 110 and the housing 31 is required to avoid electrically shocking someone who handles the DPU 10 and to avoid transmitting lightning or external shocks along the cables 40, 41 to the electronics and other equipment, or users. The casing 31 does not have an external earthing or grounding point. Consequently, the support structure 70, 80, described in more detail below, and which forms part of sub-assembly 300, is devised to support the PCBA 110 in electrically isolated manner within casing 31. Furthermore, heat generated by electric components on the PCBA 110 has to be transferred from within the casing 31 to the DPU's surroundings. In accordance with one inventive concept of the present invention, the DPU 10 is provided with heat sink bodies 50, 60 to manage the temperature of its electronics. The DPU 10 has a top heat sink 50 located at the upper side of the DPU 10 and a base heat sink 60 located at the lower side of the DPU 10. These heat sinks 50, 60 cooperate with casing 31 to conduct heat towards heat-radiating structures (such as fins or ribs) formed integrally on exterior surfaces of the casing 31.

Heat Sinks

In the preferred embodiment, the heat sinks 50, 60 are die cast bodies made from the same aluminium as casing 31.

Using heat sink body 60 as an example, the board-facing surface 62 of heat sink body 60 (but similarly that of heat sink body 50) is structured and shaped to reflect the lay-out and shape of critical heat generating components carried on the surface of PCBA 110 which faces the respective heat sink 50, 60. These DPU components will typically include the optical interface (BOSA), main processors, DSL line drivers and other minor components. The heat sink bodies 50, 60 are also structured and shaped to accommodate the placement of thermal pads 90, 100 which are described in detail below, between their board-facing surfaces 52, 62 and the PCBA 110.

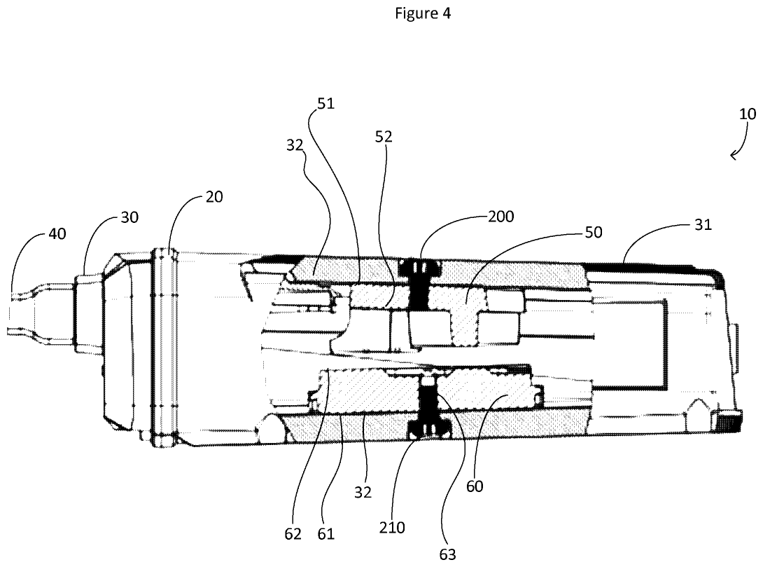

As is best seen in FIG. 4, both heat sink bodies 50, 60 have a substantially smooth and planar casing-facing (outer) surface 51, 61 which mirrors the structure of the inward facing inner surface 32 of casing 31, thereby enabling substantially air-gap-free planar abutment of these surfaces against each other, for reasons explained below.

It will be further noted that the foot-print size of bottom heat sink 60 is larger than that of upper heat sing body 50. The lower side heat sink 60 contacts a large area of the PCBA 110 because there are mainly low-profile components on the underside of the PCBA 110 that press into the thicker thermal base pad 100.

As noted, the heat sink bodies 50, 60 have a predetermined shape and structure taking into account the geometry and topography of the main PCBA 110 and daughter PCBA 120 to ensure a close fit which brings the heat sink bodies 50, 60 in very close proximity to the main PCBA 110 and daughter PCBA 120. Electrical isolation and the shape and location of daughter PCBA 120 are also considered when determining the shape for the heat sink bodies 50, 60. The daughter PCBA 120 covers part of the top side of the PCBA 110 and also some components are relatively high or have a complex shape. These factors also determine an optimal shape for the heat sinks 50, 60. Thermal imaging may be initially performed to identify the heat generating areas to optimally determine the topography of the board facing side 52, 62 of the heat sink bodies 50, 60.

The profiling of the heat sink bodies 50, 60 allows for good direct thermal contact (via the thermal pads 90, 100) to certain PCBA component bodies having a variable height. The contact surface area is maximised. The grade of aluminium used for the heat sink bodies 50, 60 ensures optimal thermal conductivity. Preferably, casting grade A413 aluminium is used.

These thermal management measures allow heat generated by power-consuming and generating components of the PCBA 110 to transfer via the thermal pads 90, 100 and heat sink bodies 50, 60 to the casing 31 and then out to the ambient environment. Within the DPU 10, these components provide direct thermal conduction paths to facilitate thermal management. The DPU 10 should also have electrical isolation between the active components and the conductive aluminium heat sink bodies 50, 60, main body 31 and end cap 20.

Manifolds

As noted above, the DPU 10 also needs to provide for electrical isolation between the active (power generating and consuming) components and the conductive aluminium heat sink bodies 50, 60, main casing 31 and end cap 20 which is also made of aluminium. Two plastic manifolds provide this functionality, a top manifold 70 and a base manifold 80 which are shaped such as to assemble into a casing that surrounds the PCBA 110. The manifolds 70, 80 operate synergistically with the heat sink bodies 50, 60 to manage the temperature and provide electrical isolation. The manifolds 70, 80 assist in positioning the heat sink bodies 50, 60 relative to the PCBAs 110, 120, by including shape conforming openings or through holes 71, 81 in which the heat sink bodies 50, 60 are received and constrained for movement to and away from the casing 31.

During assembly, the manifold halves 70, 80 are joined together, with the PCBA 110 and thermal pads 90, 100 housed within the cavity defined by the two manifolds 70, 80, and secured to each other using mechanical fasteners, for example, 6 screws or plastic pins 301. The plastic pins 301 are inserted into sockets integrally formed in the manifolds 70, 70 and are secured during assembly via an interference fit. The heat sink bodies 50, 60 are then inserted into the receptacles 71, 81 to form a single unit (completed sub-assembly 300). Cooperating guide and placement/support structures are present on the outside of the manifolds 70, 80 and at the inner surfaces of casing 31, thereby allowing sub-assembly 300 to easily slide into and be properly located within the DPU casing 31. The open side of the DPU 10 is then covered by the end cap 20 to provide a sealed DPU 10.

The heat sink bodies 50, 60 and PCBA 110 are held in place during assembly by the plastic manifolds 70, 80. The plastic manifolds 70, 80 also provide critical electrical isolation of the components of the PCBA 110 from the casing 31 by avoiding direct physical contact between the PCBA 110 and the casing 31 when the DPU 10 has been installed.

As can be seen in FIG. 2, a separate manifold 130 is provided to cover and protect the daughter PCBA 120.

Thermal Pads

The thermal pads 90, 100 are placed on the upper and lower surface of the PCBA 110 during assembly of the sub-assembly 300. In use, the heat sink bodies 50, 60 rest against these pads 90, 100 to draw heat away from the electronics. These pads 90, 100 conduct heat and are also electrically insulative to electrically isolate the heat sink bodies 50, 60. The thermal pads 90, 10 are elastomeric, heat-conductive and electrically isolating. The thermal pads 90, 100 are sandwiched between the two aluminium heat sink bodies 50, 60 and the PCBA 110, respectively, and are held in place during assembly by the plastic manifolds 70, 80.

The two electrically isolating and thermally conductive pads 90, 100 fill the space and air gaps between the electrical components and the profiled, board-facing surfaces 52, 62 of heat sink bodies 50, 60, preferably with a 0.2 mm interference. This interference ensures the thermal pads 90, 100 remain securely in position and retain good thermal contact to the surface of both the heat sink bodies 50, 60 and the PCBA 110.

The material for the pads 90, 100 has a high electrical insulation rating. Preferably, the material is a silicone elastomer loaded with thermal conductive filler. More preferably, the material is a thermal conductive silicone rubber. Even more preferably, the material is SR-1000C thermal conductive silicone rubber. A minimum 1 mm thickness for the thermal pads 90, 100 when installed exceeds the isolation requirements for the DPU 100. In one embodiment, the top pad 90 is 1.2 mm thick (to accommodate the 0.2 mm interference fit referred to above) and the base pad 100 is 2 mm thick. If adjacent components are located close to but outside the footprint of the heat sink bodies 50, 60 on the PCBA 110, it is preferred for a portion of the thermal pads 90, 100 to drape or cover these components too, and extend beyond the perimeter edge of the heat sink bodies 50, 60 and provide improved electrical isolation.

Mechanical Fastener for Positive Connection Between Casing and Heat Sinks

Since thermal conductivity increases with pressure between metal surfaces, the heat sink bodies 50, 60 are secured positively to the main body 31 through respective mechanical pressure joints, whereby an optional thermal paste/thermal grease film can be present at the interface. To this end, tamper proof sealing screws 200, 210 are used (e.g. M6 thread). These are fastened to the heat sink bodies 50, 60 in their threaded holes 53, 63 and extend through the upper and lower walls, respectively, of casing 31 and have their screw heads located in respective holes in the upper and lower walls, such that these can be tightened from the exterior of the casing 31, a top screw 200 being screwed into a threaded hole 53 located about the centre of the top heat sink body 50 and a base screw 210 being screwed into a threaded hole 63 located about the centre of the base heat sink body 60.

To ensure the DPU 10 remains hermetically sealed during prolonged use in a harsh environment, the M6 sealing screws 200, 210 each are provided with a integral deformable radial sealing member (e.g. an o-ring) providing a radial and axial seal at the screw holes 201 when they are tightened. The screws 200, 210 may be tightened with a torque driver. As the sealing screws 200, 210 are fastened to their maximum limit, they draw or pull the heat sink bodies 50, 60 outwards towards and into pressured abutment against the inner surface of the housing 31 and maximises the contact surface area. This positive (or pressure connection) enhances thermal conduction between the heat sinks 50, 60 and the inner surface of the casing 31 which then radiates into the environment from the outer, profiled surface of casing 31.

Although a sealing screw has been described, wherein the sealing arrangement is at the screw head via the o-ring, other or additional sealing mechanisms can be used, e.g. a seal or packing surrounding the inner surface of the through-holes 201 of the housing 31 for screws 200, 210.

In contrast to prior DPUs, the heat sink bodies 50, 60 are positively connected to the main body 31 by the M6 tamper proof sealing screws 200, 210 rather than relying solely on the elasticity of the thermal pads 90, 100 to make and maintain the critical thermal connection.

That is, the features of the DPU 10 contributing to thermal management include the combined contributions provided by the (profiled, die-cast aluminium) heat sink bodies 50, 60, the electrically isolating thermal pads 90, 100, and the positive securement of the heat sink bodies 50, 60 in surface-abutting relationship against the inner surface of the outer casing 31 through the mechanical fasteners 200, 210.

The completed sub-assembly 300 comprising the PCBA 110, manifolds 70, 80, thermal pads 90, 100 and heat sink bodies 50, 60 is assembled into the casing 31 along its internal draft using a small amount of the thermal grease applied on the contact surface of the heat sinks 50, 60. For example, FUMIO FUC-03 thermal grease 0.78 W/m/k is used. The thermal paste/thermal grease assists with heat conduction.

The contact between the heat sink bodies 50, 60 and main body 31 is enhanced because the contact provided in the preferred embodiment does not solely rely on the resilience of the thermal pad 90, 100. There is a risk that the thermal pads 90, 100 may relax over time. Since the DPU 10 should have long term reliability, eliminating this risk as a cause for potential malfunction of the DPU 10 is advantageous.

Unless specified to the contrary, any and all components herein described are understood to be capable of being manufactured and, as such, may be manufactured together or separately.

Moreover, in interpreting the disclosure, all terms should be interpreted in the broadest reasonable manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Although the technology herein has been described with reference to particular examples, it is to be understood that these examples are merely illustrative of the principles and applications of the technology. In some instances, the terminology and symbols may imply specific details that are not required to practice the technology. For example, although the terms “first” and “second” may be used, unless otherwise specified, they are not intended to indicate any order but may be utilised to distinguish between distinct elements.

It is therefore to be understood that numerous modifications may be made to the illustrative examples and that other arrangements may be devised without departing from the spirit and scope of the technology.

1. A Distribution Point Unit (DPU), comprising:
an at least partially metallic housing having an exterior surface and interior surface;
an electronic board including electronic components housed within the housing;
at least one heat sink housed in displaceable manner within the housing and configured to conduct heat generated by at least some of the electronic components at the electronic board into the housing;
at least one resilient thermal pad placed between one side of the electronic board and the heat sink in at least partial, physical contact making engagement, the thermal pad being heat conductive and electrically insulating to electrically isolate the first heat sink from the electronic board components; and
at least one mechanical fastener engaging with the heat sink and operable from an exterior of the housing, the arrangement being such that in response to tightening of the mechanical fastener (i) the heat sink is pressed against the interior surface of the housing to maintain contact and preferably a force fit between the heat sink and the interior surface and (ii) the heat conducting engagement between the thermal pad, the heat sink and components of the electronic board is maintained.

2. The DPU of claim 1, wherein a heat dissipation path formed by and between the electrical board components, the thermal pad, the heat sink and the housing is substantially free of an air gap.

3. A Distribution Point Unit (DPU) having improved thermal management and electrical isolation, comprising:
an at least partially metallic housing comprising an exterior surface and interior surface;
an electronic board including electronic components housed within the housing;
a first resilient thermal pad placed on a first side of the electronic board;
a first heat sink configured to rest against the first thermal pad; and
a first mechanical fastener that is operable from an exterior of the housing and which engages with the first heat sink, the arrangement being configured to draw the first heat sink against the interior surface of the housing in response to tightening of the first mechanical fastener whereby intimate physical contact between the first heat sink and the interior surface of the housing is achieved; and
wherein the first thermal pad is heat conductive and electrically insulative to electrically isolate the first heat sink.

4. The DPU according to claim 3, wherein a heat dissipation path between electronic board components, first thermal pad, first heat sink and the at least partially metallic housing is substantially free of an air gap.

5. The DPU according to claim 3, further comprising:
a second resilient thermal pad placed on a second side opposite the first side of the electronic board;
a second heat sink configured to rest against the second thermal pad; and
a second mechanical fastener that is operable from the exterior of the housing and which engages with the second heat sink, the configuration being such as to draw the second heat sink against the interior surface of the housing in response to tightening of the second mechanical fastener whereby positive contact between the second heat sink and the interior surface of the housing is achieved; and
wherein the second thermal pad is heat conductive and electrically insulative to electrically isolate the second heat sink.

6. The DPU according to claim 1, further comprising a single or multi-piece manifold configured to support the electronic board and prevent physical contact between the electronic board and the housing, and for positioning the heat sink(s) relative to the electronic board.

7. The DPU according to claim 6, wherein the manifold is at least partially made from electrically insulating material and optionally comprises materials conducive to heat transfer.

8. The DPU according to claim 1, wherein the at least one mechanical fastener comprises a deformable radial sealing member.

9. The DPU according to claim 8, wherein the mechanical fastener is a sealing screw with an o-ring.

10. The DPU according to claim 1, wherein at least one of the first and second thermal pad(s) is/are made from a silicone elastomer loaded with thermal conductive filler.

11. The DPU according to claim 1, wherein at least one of the first and second thermal pad(s) is/are made from SR-1000C thermal conductive silicone rubber.

12. The DPU according to claim 5, wherein the second thermal pad is thicker than the first thermal pad.

13. The DPU according to claim 5, wherein the second heat sink is larger by mass or size than the first heat sink.

14. The DPU according to claim 1, wherein the first and second heat sinks comprise each a metallic body with a threaded hole to receive the associated first and second mechanical fastener, respectively, and wherein the hole is located about a centre of the metallic heat sink body.

15. The DPU according to claim 1, wherein the first and second heat sinks exhibit a substantially planar engagement surface adapted for planar abutment against the inner surface of the at least partially metallic housing, thereby to provide an increased heat transfer area.

16. The DPU according to claim 1, wherein the exterior surface of the at least partially metallic housing is provided with heat dissipation ribs or heat radiation fins.

17. The DPU according to claim 3, wherein at least one of the first and second mechanical fasteners comprises a deformable radial sealing member.

18. The DPU according to claim 17, wherein the first and second mechanical fasteners are comprised of a sealing screw with an o-ring, respectively.

19. The DPU according to claim 3, further comprising a single or multi-piece manifold configured to support the electronic board and prevent physical contact between the electronic board and the housing, and for positioning the heat sink(s) relative to the electronic board.

20. The DPU according to claim 5, wherein at least one of the first and second thermal pad(s) is/are made from a silicone elastomer loaded with thermal conductive filler.
